(19) United States
(12) Patent Application Publication
(10) Pub. No.: US 2025/0207718 A1
(43) Pub. Date: Jun. 26, 2025

(54) DISPLAY DEVICE

(71) Applicant: Samsung Display Co., Ltd., Yongin-sI (KR)

(72) Inventors: BEOMJIN KIM, Yongin-si (KR); JIYEON KIM, Yongin-si (KR); JAEHO AHN, Yongin-si (KR); CHEOL JANG, Yongin-si (KR)

(73) Assignee: Samsung Display Co., Ltd., Yongin-si (KR)

(21) Appl. No.: 18/940,470

(22) Filed: Nov. 7, 2024

(30) Foreign Application Priority Data
Dec. 21, 2023 (KR) 10-2023-0188024

(51) Int. Cl. F16M 11/10; H10K 77/10; H10K 102/00

(52) U.S. Cl. CPC F16M 11/105; H10K 77/111; H10K 2102/311

(57) ABSTRACT

A display device including a display module, a support part disposed below the display module, a dummy part extended to an end of the support part, and a shaft which may extend to an end of the dummy part and which may have a rotary axis extending in a first direction, the display module may be wound or unwound about the shaft. The support part, the dummy part, and the shaft may include the same resin.

### CROSS-REFERENCE TO RELATED APPLICATIONS

This application claims priority under 35 U.S.C. § 119 from Korean Patent Application No. 10-2023-0188024 filed on Dec. 21, 2023 in the Korean Intellectual Property Office, the entire contents of which are incorporated herein by reference.

### BACKGROUND

### 1. Technical Field

The disclosure herein relates to a display device.

### 2. Description of the Related Art

Electronic devices such as smartphones, digital cameras, notebook computers, navigation devices and smart televisions which provide users with images include display devices for displaying images. The display devices generate images and provide users with the images through display screens.

Recently, display devices having various shapes are being developed along with the technical development of the display devices. For example, various flexible display devices capable of being changed into curved, folded, or rolled shapes are being developed. The flexible display devices may be portable and improve users' convenience.

Among the flexible display devices, rollable display devices may include display modules, and module support parts disposed below the display modules.

### SUMMARY

The disclosure provides a display device with improved surface quality.

In an embodiment of the disclosure, a display device may include a display module, a support part disposed below the display module, a dummy part extending to an end of the support part, and a shaft extending to an end of the dummy part, the shaft having a rotary axis extending in a first direction, the display module being wound on or unwound from the shaft. The support part, the dummy part, and the shaft may include a same resin.

A thickness of the dummy part may be greater than a thickness of the support part.

A difference between a height of a top surface of the display module disposed on the support part and a height of a top surface of the dummy part may be in a range of about 0 micrometer to about 50 micrometers.

In case that the display module is wound on the shaft, a difference between a distance from the rotary axis to an outer circumference of the shaft and a distance from the rotary axis to an outer circumference of the dummy part may be in a range of about 0 micrometer to about 50 micrometers at a boundary between the shaft and the dummy part.

A radius of the shaft, which may be defined as a distance from the rotary axis to an outer circumference of the shaft, may vary.

The support part may include a resin layer including the resin, and a support body disposed in the resin layer.

The support body may include a plurality of support bars extending in the first direction and arranged in a second direction intersecting the first direction.

The support body may include a support plate in which a plurality of opening portions may be defined.

The support part, the dummy part, and the shaft may be integral with each other.

The shaft may include a sub-shaft extending in the first direction, and a coating part configured to surround the sub-shaft, the coating part may contain the resin.

The resin may have an elastic modulus in a range of about 0.2 MPa to about 1 MPa.

In case that the display module is wound on the shaft, a bottom surface of the dummy part may be in contact with an outer circumference of the shaft.

A bottom surface of the support part may be in contact with a portion of the dummy part and a portion of the shaft, each of which may be adjacent to a boundary between the dummy part and the shaft.

In an embodiment of the disclosure, a display device may include a display module, a shaft which includes a first stepped portion provided at an outer circumference of the shaft, and an extension part extending from the first stepped portion, the extension part may be wound on or unwound from the shaft together with the display module. The extension part may include a dummy part extending from the first stepped portion, and a support part extending from the dummy part in a first direction, the support part may be disposed below the display module. A second stepped portion may be provided at a boundary between the dummy part and the support part.

A curvature of the shaft adjacent to the first stepped portion may be equal to a curvature of the dummy part adjacent to the first stepped portion.

In case that the display module is wound, the support part may be wound along at least one of an outer circumference of the dummy part or an outer circumference of the shaft.

In case that the display module is wound, a curvature of the dummy part adjacent to the second stepped portion may be equal to a curvature of the support part adjacent to the second stepped portion.

The shaft may have at least two different curvatures.

The support part, the dummy part, and the shaft may be integral with each other.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a perspective view of a display device according to an embodiment of the disclosure;

FIG. 2 is a view illustrating a display module drawn out of a housing illustrated in FIG. 1;

FIG. 3 is a schematic cross-sectional view taken along line I-I′ illustrated in FIG. 1;

FIG. 4 is a schematic cross-sectional view taken along line II-II′ illustrated in FIG. 2;

FIG. 5 is a perspective view of a support part PT2 illustrated in FIG. 4;

FIG. 6 is a schematic cross-sectional view taken along line III-III′ illustrated in FIG. 5;

FIG. 7 is a view for explaining a shaft according to an embodiment of the disclosure;

FIG. 8 is a perspective view for explaining support bars illustrated in FIG. 5;

FIGS. 9A to 9C are views for explaining a support body according to an embodiment of the disclosure;

FIG. 10 is a view illustrating the display module accommodated in the housing illustrated in FIG. 2;

FIG. 11 is a view illustrating a state in which the display module illustrated in FIG. 10 is wound;

FIG. 12 is a view illustrating an example of a schematic cross-section of the display module illustrated in FIG. 10;

FIG. 13 is a view illustrating an example of a schematic cross-section of a display panel illustrated in FIG. 12;

FIG. 14 is a plan view of the display panel illustrated in FIG. 13; and

FIGS. 15A to 15H are views for explaining a method for manufacturing the support part illustrated in FIG. 5.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described in more detail with reference to the accompanying drawings.

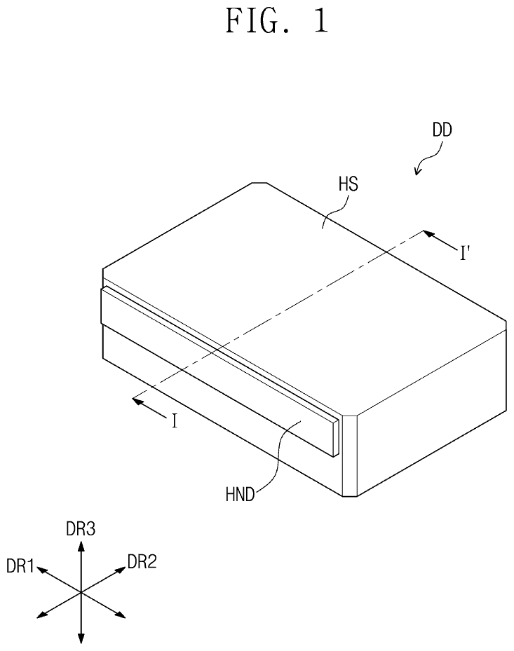

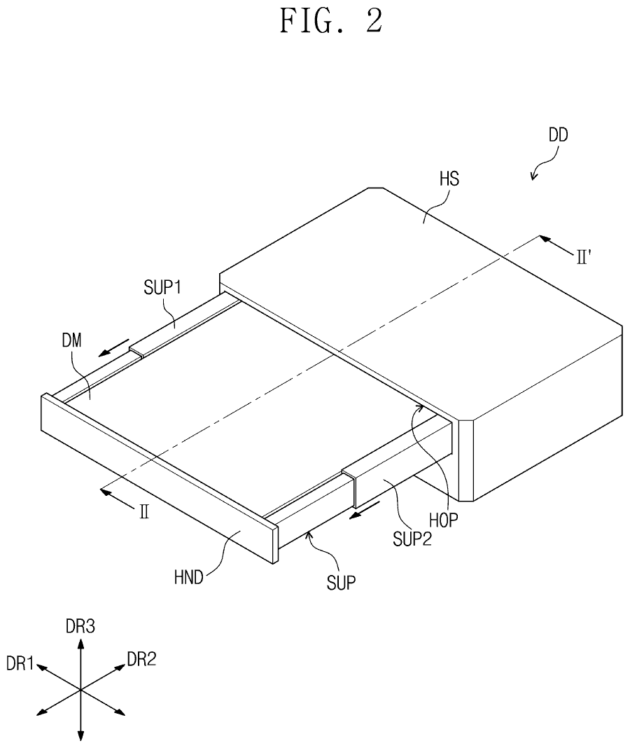

FIG. 1 is a perspective view of a display device according to an embodiment of the disclosure. FIG. 2 is a view illustrating a display module drawn out of a housing illustrated in FIG. 1.

Referring to FIGS. 1 and 2, a display device DD according to an embodiment of the disclosure may include a housing HS, a display module DM accommodated in the housing HS, a handle HND connected to the display module DM, and a support SUP adjacent to both sides of the display module DM.

The housing HS may have a hexahedral shape. A top surface of the housing HS may have a rectangular shape having long sides extending in a first direction DR1 and having short sides extending in a second direction DR2 intersecting the first direction DR1. However, the shape of the housing HS is not limited thereto.

Hereinafter, a direction substantially perpendicularly intersecting a plane defined by the first and second directions DR1 and DR2 may be defined as a third direction DR3. The clause “when viewed on a plane” herein may mean a state when viewed in the third direction DR3 or when viewed in a plan view.

A housing opening portion HOP may be defined in one of both sides of the housing HS, which may be opposite to each other in the second direction DR2. The housing opening portion HOP may be more adjacent to an upper portion of the housing HS than to a lower portion of the housing HS.

The display module DM may be wound on a shaft disposed in the housing HS to be drawn in and out through the housing opening portion HOP. However, an embodiment of the disclosure is not limited thereto, and the display module DM may slide from the inside to the outside of the housing HS to be drawn out to the outside without using the shaft. The configuration in which the display module DM may be wound on the shaft will be described later in detail.

The handle HND may be disposed outside the housing HS to be adjacent to the housing opening portion HOP. The handle HND may be adjacent to the upper portion of the housing HS. The handle HND may move in the second direction DR2. In case that the handle HND moves in the second direction DR2 so as to be away from the housing HS, the display module DM may be drawn out of the housing HS toward the housing opening portion HOP. The handle HND may be operated by a user.

As illustrated in FIG. 1, a state in which the display module DM may be disposed inside the housing HS and may not be exposed to the outside may define as a closed mode. As illustrated in FIG. 2, an operation in which the display module DM may be exposed to the outside may define as an open mode. In the open mode, an exposed portion of the display module DM may extend.

The support SUP may be disposed on both the sides of the display module DM, which are opposite to each other in the first direction DR1, to support the display module DM. The support SUP may include a first support SUP1 adjacent to a side of the display module DM, and a second support SUP2 adjacent to another side of the display module DM. The side of the display module DM and another side of the display module DM may be both sides of the display module DM that are opposite to each other in the first direction DR1.

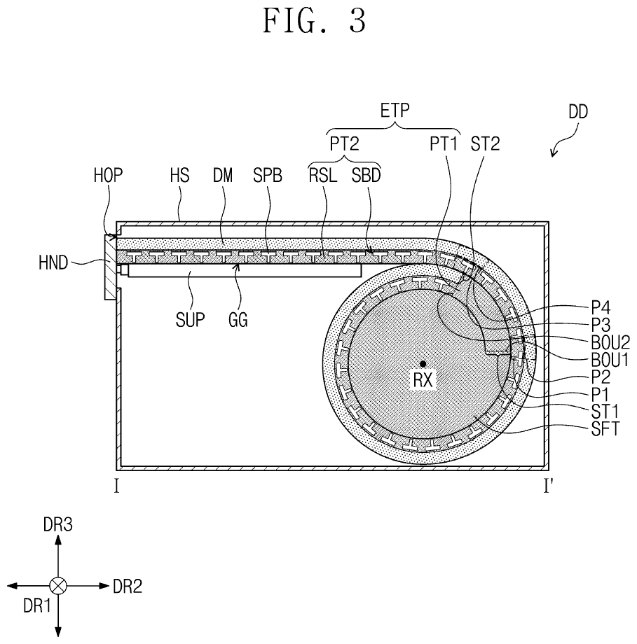

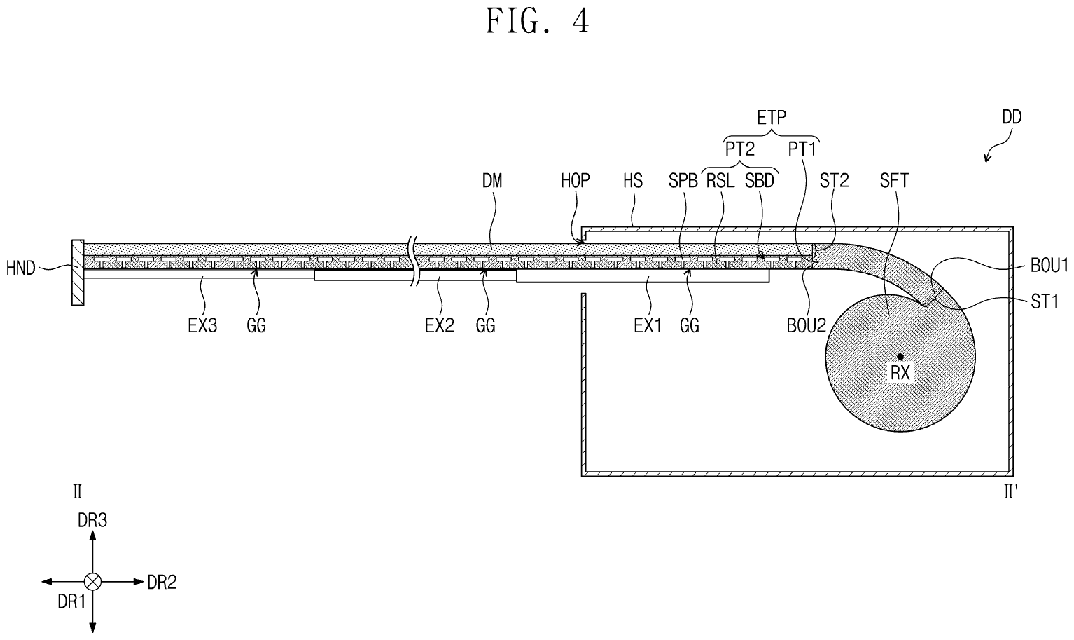

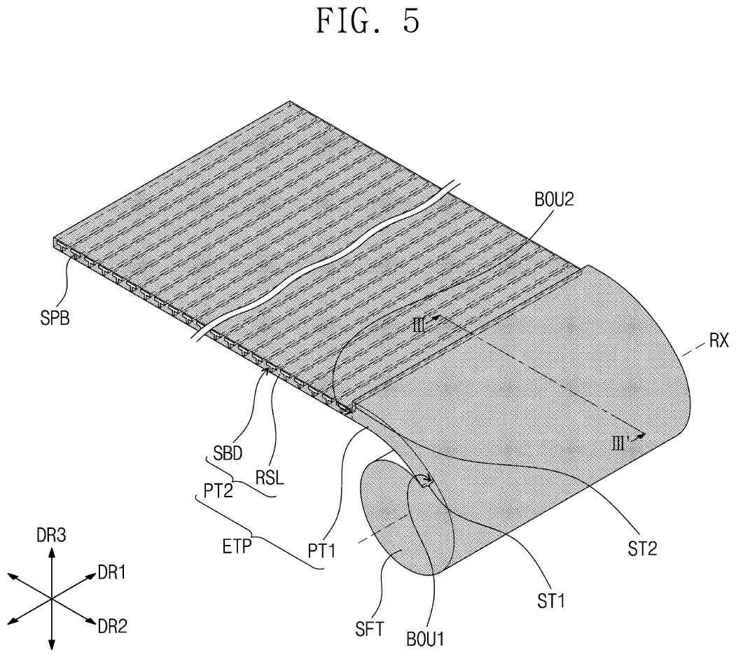

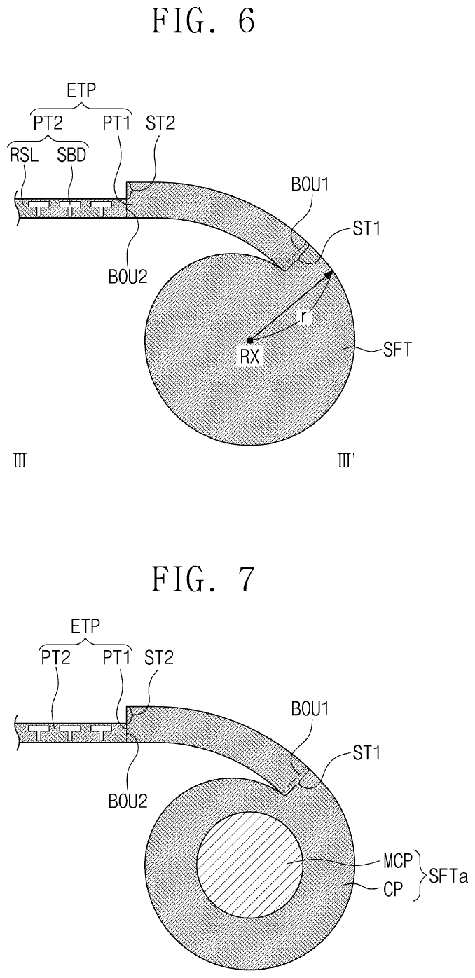

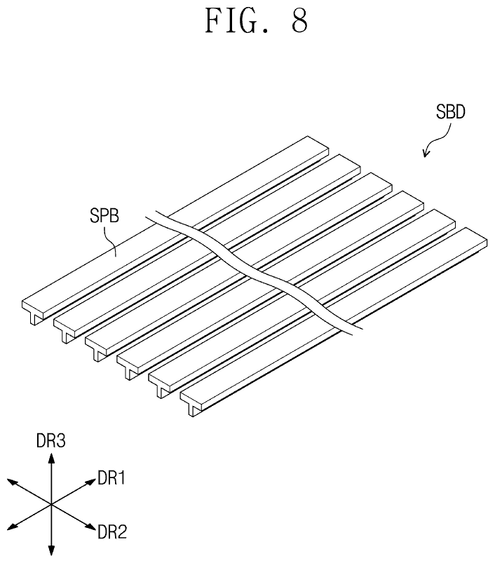

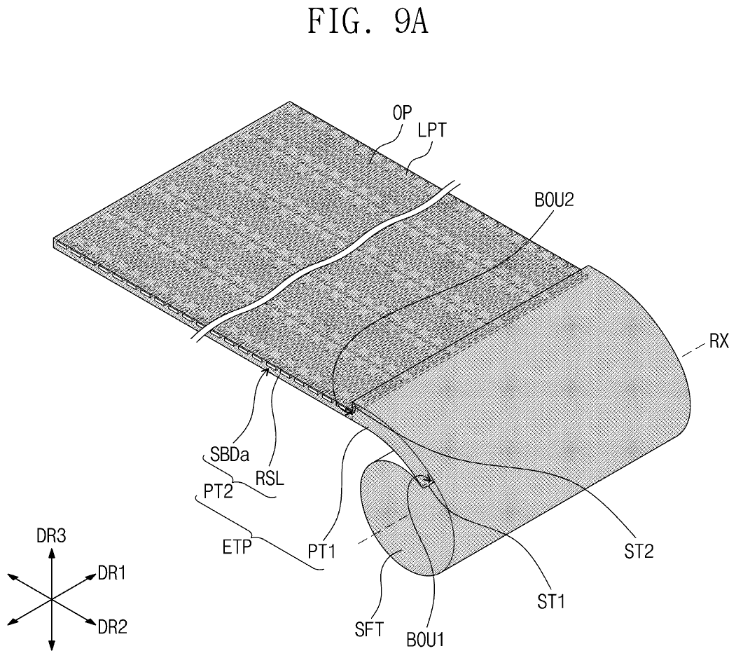

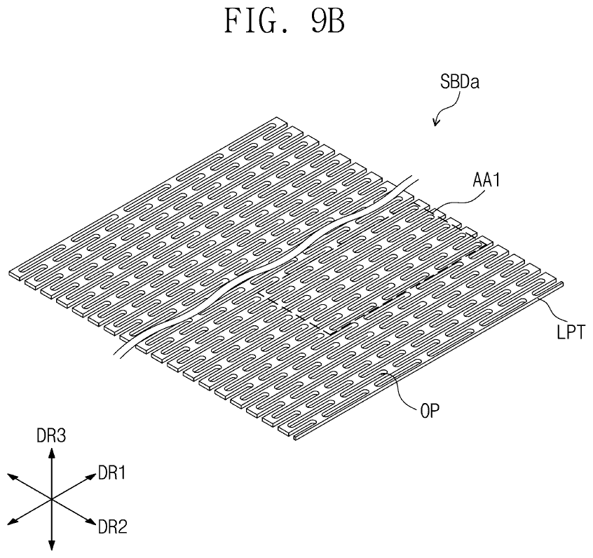

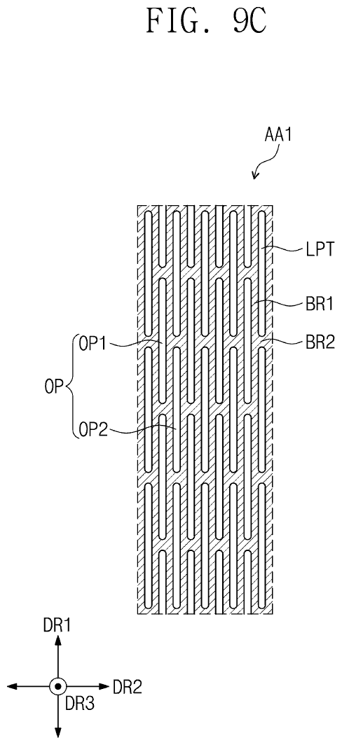

FIG. 3 is a schematic cross-sectional view taken along line I-I′ illustrated in FIG. 1. FIG. 4 is a schematic cross-sectional view taken along line II-II′ illustrated in FIG. 2. FIG. 5 is a perspective view of a shaft SFT and an extension part ETP illustrated in FIG. 4. FIG. 6 is a schematic cross-sectional view taken along line III-III′ illustrated in FIG. 5. FIG. 7 is a view for explaining a shaft according to an embodiment of the disclosure. FIG. 8 is a perspective view for explaining support bars illustrated in FIG. 5. FIGS. 9A to 9C are views for explaining a support body according to an embodiment of the disclosure.

As an example, FIGS. 9A and 9B each illustrate a perspective view, and FIG. 9C is a plan view of a first area AA1 illustrated in FIG. 9B.

As an example, FIGS. 4 to 7 and 9A are views illustrating the extension part ETP in the open mode.

A shaft SFT, a dummy part PT1, and a support part PT2 illustrated in FIGS. 9A to 9C are substantially the same as the shaft SFT, a dummy part PT1, and a support part PT2 illustrated in FIG. 5, respectively, and thus redundant description will be omitted.

Referring to FIGS. 3 and 4, the display device DD may include the housing HS, the display module DM, the shaft SFT, the extension part ETP, the support SUP, and the handle HND. The display module DM, the shaft SFT, the extension part ETP, and the support SUP may be accommodated in the housing HS.

Referring to FIGS. 3 and 5 to 7, the shaft SFT may be inside the housing HS and adjacent to a side opposite to a side of the housing HS in which the housing opening portion HOP may be defined. The shaft SFT may rotate around a rotary axis RX parallel to the first direction DR1 in clockwise and counterclockwise directions. Although not illustrated, the display device DD may further include a driving part for rotating the shaft SFT.

The shaft SFT may have at least two curvatures. Specifically, a size of a radius of the shaft SFT may be variable when viewed in the first direction DR1. The radius of the shaft SFT may be defined as a length from the rotary axis RX to an outer circumference of the shaft SFT. The length from the rotary axis RX of the shaft SFT to the outer circumference of the shaft SFT may be variable. For example, as illustrated in FIG. 6, the shaft SFT may have a spiral shape. The outer circumference of the shaft SFT may be defined as a surface of the shaft SFT that faces a bottom surface of the display module DM in a closed state of the display module DM.

The shaft SFT may include a resin. The resin may be a polymer having elasticity. For example, the shaft SFT may include silicone or polyurethane acrylate. The resin of the shaft SFT may have an elastic modulus in a range of about 0.2 MPa to about 1 MPa.

Unlike the shaft SFT illustrated in FIG. 6, a shaft SFTa illustrated in FIG. 7 may include a sub-shaft MCP including a metal, and a coating part CP including a resin. As an example, the sub-shaft MCP may have a circular shape when viewed in the first direction DR1. The coating part CP may surround the sub-shaft MCP. As the sub-shaft MCP may be disposed inside the shaft SFTa, rigidity of the shaft SFTa may be increased.

Referring to FIG. 3, the display module DM may extend in the second direction DR2 to be wound on the shaft SFT. The display module DM may extend to the shaft SFT through the extension part ETP to be described later. A portion of the display module DM may be wound on the shaft SFT, and another portion of the display module DM may be disposed to overlap the support SUP without being wound on the shaft SFT. The another end of the display module DM, which may be an end opposite to an end of the display module DM, may connected to the handle HND. Another end of the display module DM may be adjacent to the housing opening portion HOP. Hereinafter, a state in which the display module DM may be wound on the shaft SFT may be defined as a rolled state. A state in which the display module DM may not be wound on (or about) the shaft SFT may be defined as an unrolled state.

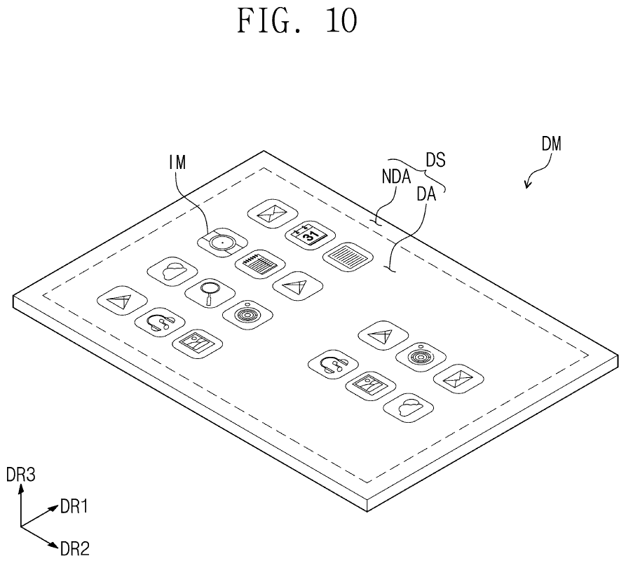

A top surface of the display module DM may be defined as a surface on which an image may be displayed. The extension part ETP may be disposed on a surface of the display module DM. The extension part ETP may be disposed on the bottom surface of the display module DM, which may be a surface opposite to the top surface of the display module DM. For example, the extension part ETP may be attached to the bottom surface of the display module DM through an adhesive. Hereinafter, the surface of the display module DM may be defined as the bottom surface of the display module DM. The display module DM will be described in detail with reference to FIGS. 10 to 14.

Referring to FIGS. 3 to 5, the extension part ETP may extend in the second direction DR2 to be wound on the shaft SFT. The extension part ETP may have an end extended to the shaft SFT, and another end connected to the handle HND. The another end of the extension part ETP may be adjacent to the housing opening portion HOP.

In the closed mode, the extension part ETP may extend from the shaft SFT in the second direction DR2 to be adjacent to the housing opening portion HOP. A portion of the extension part ETP may be wound on the shaft SFT, and another portion of the extension part ETP may be disposed to overlap the support SUP without being wound on the shaft SFT.

The extension part ETP may include a resin. The resin may be a polymer having elasticity. For example, the extension part ETP may include silicone or polyurethane acrylate. The extension part ETP and the shaft SFT may include a same material. The resin of the extension part ETP may have an elastic modulus in a range of about 0.2 MPa to about 1 MPa.

Referring to FIGS. 3 to 6, the extension part ETP may include the dummy part PT1 and the support part PT2. The dummy part PT1 may have an end extended to the shaft SFT. Specifically, the end of the dummy part PT1 may have an end extended to a first stepped portion ST1 of the shaft SFT. The dummy part PT1 may have a structure extending from the first stepped portion ST1 of the shaft SFT, and substantially the dummy part PT1 and the shaft SFT may have a structure provided as a body. The first stepped portion ST1 may define a first boundary BOU1 between the dummy part PT1 and the shaft SFT.

A stepped portion may not be provided between an outer circumference of the dummy part PT1 and an outer circumference of the shaft SFT at the first boundary BOU1 between the dummy part PT1 and the shaft SFT. A curvature of the outer circumference of the dummy part PT1 and a curvature of the outer circumference of the shaft SFT may be the same as each other at the first boundary BOU1. A difference between a distance from the rotary axis RX to the outer circumference of the dummy part PT1, which may be adjacent to the first boundary BOU1, and a distance from the rotary axis RX to the outer circumference of the shaft SFT, which may be adjacent to the first boundary BOU1, may be in a range of about 0 micrometer to about 50 micrometers at the first boundary BOU1. In case that the display module DM is in the rolled state, the outer circumference of the dummy part PT1 and the outer circumference of the shaft SFT may be defined, respectively, as a surface of the dummy part PT1 and a surface of the shaft SFT, each of which faces the bottom surface of the display module DM.

The dummy part PT1 may have another end extended to the support part PT2. The support part PT2 may be disposed on the bottom surface of the display module DM. The support part PT2 may support the display module DM from below the display module DM.

The support part PT2 may have an end extended to the dummy part PT1. The support part PT2 may have a structure extending from another end of the dummy part PT1, and substantially the dummy part PT1 and the support part PT2 may be provided as a body. For example, the extension part ETP, which includes the dummy part PT1 and the support part PT2, and the shaft SFT may be provided as a body.

The dummy part PT1 may have a thickness that may be greater than a thickness of the support part PT2. According to an embodiment, a height of a top surface of the dummy part PT1 may be greater than a height of a top surface of the support part PT2 at a second boundary BOU2 between the dummy part PT1 and the support part PT2. Thus, the extension part ETP may have a second stepped portion ST2 at the second boundary BOU2.

In the closed mode, a portion of the extension part ETP may be wound on (or about) the shaft SFT, and another portion of the extension part ETP may be disposed to overlap the support SUP without being wound on the shaft SFT. The dummy part PT1 may be wound along the outer circumference of the shaft SFT. A bottom surface of the dummy part PT1 may be in contact with the outer circumference of the shaft SFT.

A portion of the support part PT2 may be wound on the shaft SFT. A bottom surface of the support part PT2 may be in contact with the shaft SFT or the outer circumference of the dummy part PT1. In case that the support part PT2 is wound, the bottom surface of the support part PT2 and the bottom surface of the dummy part PT1, each of which may be adjacent to the boundary between the support part PT2 and the dummy part PT1, may have the same curvature. Another portion of the support part PT2 may be disposed to overlap the support SUP without being wound on the shaft SFT. Another end of the support part PT2, which may be an end opposite to the an end of the support part PT2, may connected to the handle HND. Another end of the support part PT2 may be adjacent to the housing opening portion HOP.

As illustrated in FIG. 3, in case that the display module DM is wound, the first boundary BOU1 may overlap the support part PT2 and the display module DM. The bottom surface of the support part PT2 may be in contact with the outer circumference of the shaft SFT and the outer circumference of the dummy part PT1, each of which may be adjacent to the first boundary BOU1. Hereinafter, a portion of the first boundary BOU1 corresponding to the support part PT2 may be defined as a first area P1, and a portion of the first boundary BOU1 corresponding to the display module DM may be defined as a second area P2.

The first area P1 may be disposed on the outer circumference of the dummy part PT1 and the outer circumference of the shaft SFT, each of which may be adjacent to the first boundary BOU1. Accordingly, a shape of the first area P1 may be changed to correspond to the outer circumference of the dummy part PT1 and the outer circumference of the shaft SFT. In case that the shape of the first area P1 is changed, a shape of the second area P2 of the display module DM, which may be disposed on the first area P1, may also be changed.

In case that the outer circumference of the dummy part PT1 and the outer circumference of the shaft SFT, each of which may be adjacent to the first boundary BOU1, have different curvature from each other, the outer circumference of the dummy part PT1 and the outer circumference of the shaft SFT, each of which may be adjacent to the first boundary BOU1, may be disposed to have a stepped portion therebetween. The shape of the first area P1 may be changed to have a stepped portion. As the shape of the first area P1 may be changed, the shape of the second area P2 of the display module DM may be changed to have a stepped portion. Accordingly, stress caused by rolling of the display module DM may be concentrated in the second area P2 of the display module DM, which overlaps the first boundary BOU1. Thus, a crease may be generated on a front surface of the display module DM that may deteriorate surface quality of the display module.

However, as the dummy part PT1 and the shaft SFT may be provided as a single body (or may be integral with each other), the outer circumference of the dummy part PT1 and the outer circumference of the shaft SFT may have the same curvature. The outer circumference of the dummy part PT1 and the outer circumference of the shaft SFT may not have a stepped portion therebetween. The shape of the first area P1 may not be changed into a shape having a stepped portion. The shape of the second area P2 disposed on the first area P1 may not be changed to have a stepped portion. Accordingly, stress caused by rolling of the display module DM may be prevented from being concentrated in the portion which overlaps the first boundary BOU1 of the display module DM. Thus, a crease may be prevented from being generated on the front surface of the display module DM to improve the surface quality of the display module DM.

The thickness of the support part PT2 may be less than the thickness of the dummy part PT1. The top surface of the dummy part PT1 and the top surface of the support part PT2 may be disposed to have a stepped portion therebetween at the second boundary BOU2 between the dummy part PT1 and the support part PT2. As an example, as illustrated in FIG. 4, the height of the top surface of the dummy part PT1 may be greater than the height of the top surface of the support part PT2 in the open mode.

The display module DM may be disposed on the top surface of the support part PT2. A thickness of the display module DM may be less than the thickness of the dummy part PT1. The sum of the thickness of the display module DM and the thickness of the support part PT2 may be equal to the thickness of the dummy part PT1. A difference between a height of the front surface of the display module DM and the height of the top surface of the dummy part PT1 may be in a range of about 0 micrometer to about 50 micrometers. Accordingly, the top surface of the dummy part PT1 and the front surface of the display module DM may not have a stepped portion therebetween on the second boundary BOU2.

As illustrated in FIG. 3, the second boundary BOU2 may overlap the support part PT2 and the display module DM in the closed mode of the display device DD. The bottom surface of the support part PT2 may be in contact with the outer circumference of the dummy part PT1 and an outer circumference of the support part PT2, each of which may be adjacent to the second boundary BOU2. A portion of the second boundary BOU2 corresponding to the support part PT2 may be defined as a third area P3, and a portion of the second boundary BOU2 corresponding to the display module DM may be defined as a fourth area P4.

The third area P3 of the support part PT2 and the fourth area P4 of the display module DM may be changed into shapes corresponding to the top surface of the dummy part PT1 and the front surface of the display module DM, each of which may be adjacent to the second boundary BOU2.

Here, as the top surface of the dummy part PT1 and the front surface of the display module DM, each of which may be adjacent to the second boundary BOU2, do not have a stepped portion therebetween, the third area P3 and the fourth area P4, each of which overlaps the second boundary BOU2, may not be changed into shapes having a stepped portion. Accordingly, stress caused by the rolling may be prevented from being concentrated in the fourth area P4 of the display module DM. Thus, a crease may be prevented from being generated on the display module DM due to the stress, and the surface quality of the display module DM may be improved.

Referring to FIGS. 3 to 5 and 8, the support part PT2 may include a support body SBD and a resin layer RSL. The resin layer RSL may be a polymer having elasticity. For example, the resin layer RSL may include silicone or polyurethane acrylate. The resin of the resin layer RSL may have an elastic modulus in a range of about 0.2 MPa to about 1 MPa.

The support body SBD may be disposed in the resin layer RSL. The support body SBD may have higher rigidity than the resin layer RSL. As an example, the support body SBD in FIGS. 3 to 5 and 8 may include multiple support bars SPB arranged in the second direction DR2. However, the support body SBD may include a plate in which multiple opening portions may be defined. A shape of the support body SBD will be described in detail with reference to FIGS. 9A to 9C.

The support bars SPB may be arranged in the second direction DR2. As an example, FIG. 5 illustrates the support bars SPB disposed in the resin layer RSL in dotted lines. The support bars SPB adjacent to each other in the second direction DR2 may be spaced a distance (e.g., predetermined or selectable distance) from each other. The support bars SPB may extend in the first direction DR1.

Both ends, which may be opposite to each other in the first direction DR1 of each of the support bars SPB may be exposed to the outside without being disposed in the resin layer RSL. Each of the support bars SPB may have a “T” shape when viewed in the first direction DR1. However, a shape of a side surface of each of the support bars SPB is not limited thereto, and the support bars SPB may have various shapes.

The support bars SPB may be provided in a rigid type. For example, the support bars SPB may include a metal. The support bars SPB may include aluminum, stainless, invar, or a combination thereof. The support bars SPB may include a metal that sticks to a magnet. However, the support bars SPB are not limited thereto, and may include a carbon fiber reinforced plastic (CFRP).

Referring to FIGS. 9A and 9B, a support body SBDa may include a support plate LPT. The support plate LPT may be disposed in the support part PT2. Both sides, which may be opposite to each other in the first direction DR1 of the support plate LPT may be exposed from the support body SBDa to the outside.

A lattice pattern may be defined in the support plate LPT. For example, multiple opening portions OP may be defined in the support plate PLT. The opening portions OP may be arranged according to a rule (e.g., predetermined or selectable rule). The opening portions OP may be arranged in a lattice shape to define the lattice pattern in the entire area of the support plate LPT.

As the opening portions OP may be defined in the entire area of the support plate LPT, a surface area of the support plate LPT may be reduced to decrease rigidity of the support plate LPT. Thus, in case that the opening portions OP are defined in the support plate LPT, flexibility of the support plate LPT may be increased compared to a case where the opening portions OP are not defined. As a result, the support plate LPT may be more readily rolled.

Referring to FIG. 9C, the opening portions OP may be arranged in the first direction DR1 and the second direction DR2. The opening portions OP may extend to be more elongated in the first direction DR1 than in the second direction DR2.

The opening portions OP may include multiple first opening portions OP1 arranged in the first direction DR1 and multiple second opening portions OP2 adjacent to the first opening portions OP1 in the second direction DR2 to be arranged in the first direction DR1. The first opening portions OP1 and the second opening portions OP2 may be misaligned (or staggered) with each other.

The support plate LPT may include first branches BR1, each of which may be disposed between the opening portions OP adjacent to each other in the second direction DR2, and second branches BR2, each of which may be disposed between the opening portions OP adjacent to each other in the first direction DR1. The first branches BR1 may extend in the first direction DR1, and the second branches BR2 may extend in the second direction DR2. The opening portions OP may be defined by the first and second branches BR1 and BR2.

Referring to FIGS. 3 and 4, the handle HND may move in the second direction DR2 so as to be away from the housing HS. According to the movement of the handle HND, the display module DM and the extension part ETP, each of which may connected to the handle HND, may move in the second direction DR2. The display module DM and the extension part ETP may be unwound from the shaft SFT, and the unwound display module DM and extension part ETP may be drawn out of the housing HS through the housing opening portion HOP. Thus, the exposed portion of the display module DM may extend.

In case that the display module DM and the extension part ETP are drawn out of the housing HS according to the movement of the handle HND, the support SUP connected to the handle HND may extend to the outside of the housing HS through the housing opening portion HOP. The support SUP may extend to the outside of the housing HS to support the display module DM from outside the housing HS.

The support part PT2 of the extension part ETP, which has moved to the outside of the housing HS, may be supported by the support SUP, and the support part PT2 supported by the support SUP may support the display module DM.

The support SUP may include a first extension EX1, a second extension EX2, and a third extension EX3 so as to extend to the outside of the housing HS. The second extension EX2 may be disposed between the first extension EX1 and the third extension EX3.

In order to have a structure capable of extending like an antenna, the second extension EX2 may be drawn in and out of the first extension EX1, and the third extension EX3 may be drawn in and out of the second extension EX2. The first extension EX1 may be disposed in the housing HS, and the second and third extensions EX2 and EX3 may move to the outside of the housing HS. The third extension EX3 may be extended to the handle HND.

A guide groove GG may be defined in each of the first, second, and third extensions EX1, EX2 and EX3. The guide grooves GG defined in the first, second, and third extensions EX1, EX2 and EX3 may be defined as continuing spaces overlapping each other in the first direction DR1.

As illustrated in FIG. 3, in case that the handle HND moves in the second direction DR2 so as to be close to the housing HS, the handle HND may be disposed outside the housing HS to be adjacent to the housing opening portion HOP. According to the movement of the handle HND, the support SUP may be decreased in length in the second direction DR2 to be disposed inside the housing HS, and the display module DM and the extension part ETP may be drawn in the housing HS.

FIG. 10 is a view illustrating the display module accommodated in the housing illustrated in FIG. 2.

The display module DM may have a rectangular shape having long sides extending in the second direction DR2 and having short sides extending in the first direction DR1. However, an embodiment of the disclosure is not limited thereto, and the display module DM may have various shapes such as a circular shape and a polygonal shape.

The top surface of the display module DM may be defined as a display surface DS, and may have a plane defined by the first direction DR1 and the second direction DR2. Images IM generated in the display module DM may be provided for users through the display surface DS.

The display surface DS may include a display area DA and a non-display area NDA around the display area DA. The display area DA may display an image, and the non-display area NDA may not display an image. The non-display area NDA may surround the display area DA, and define an edge of the display module DM, which may be printed to have a color (e.g., predetermined or selectable color).

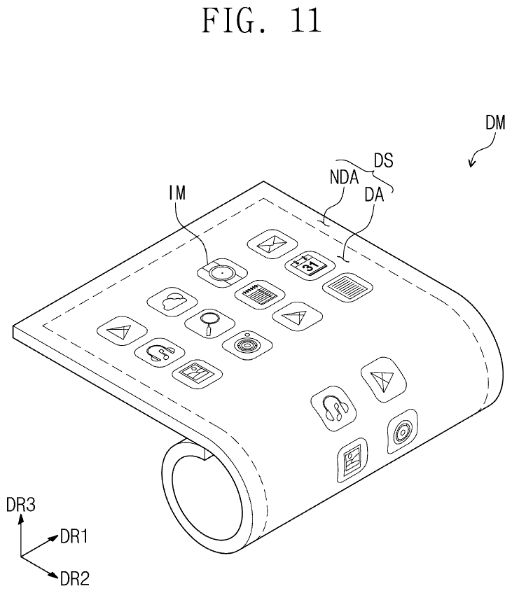

FIG. 11 is a view illustrating a state in which the display module illustrated in FIG. 10 may be wound.

Referring to FIG. 11, the display module DM may be a flexible display module. The display module DM may be rolled like a roll. The display module DM may be rolled in the second direction DR2. The display module DM may be rolled starting from a side of the display module DM. The display module DM may be rolled so that the display surface DS faces the outside. However, an embodiment of the disclosure is not limited thereto, and the display module DM may be rolled so that the display surface DS faces the inside.

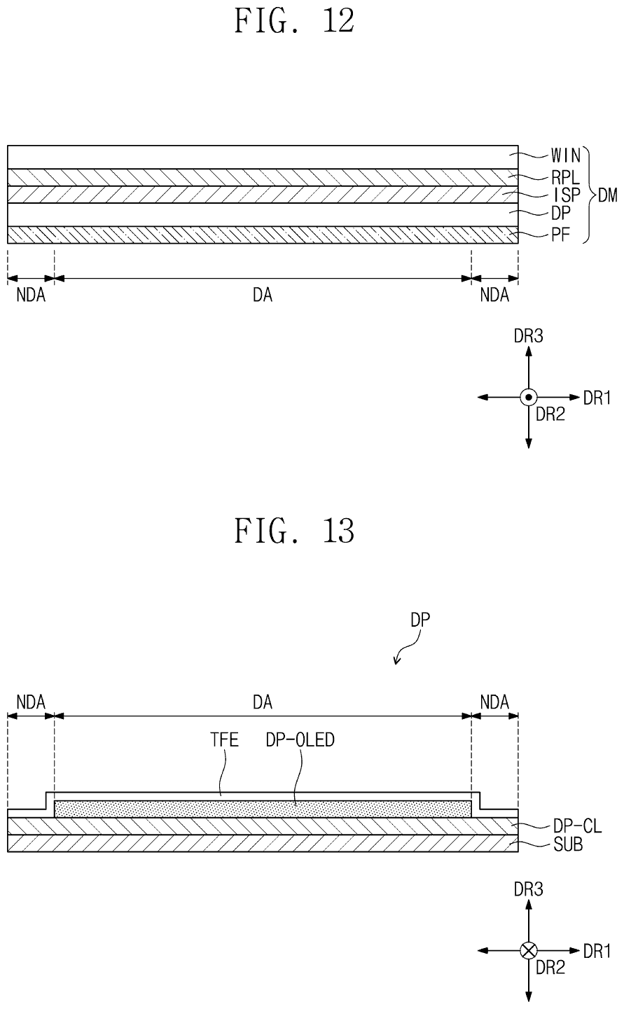

FIG. 12 is a view illustrating an example of a schematic cross-section of the display module illustrated in FIG. 10.

As an example, FIG. 12 illustrates a schematic cross-section of the display module DM viewed in the second direction DR2.

Referring to FIG. 12, the display module DM may include a display panel DP, an input sensing part ISP, an anti-reflection layer RPL, a window WIN, and a panel protective film PF.

The display panel DP may be a flexible display panel. The display panel DP according to an embodiment of the disclosure may be a light emitting display panel, and is not particularly limited. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, and the like. Hereinafter, the display panel DP may be described as the organic light emitting display panel.

The input sensing part ISP may be disposed on the display panel DP. The input sensing part ISP may include multiple sensers (not illustrated) for sensing an external input by using a capacitance method. The input sensing part ISP may be manufactured on (e.g., directly on) the display panel DP during manufacture of the display device DD. However, an embodiment of the disclosure is not limited thereto, and the input sensing part ISP may be manufactured as a separate panel from the display panel DP to be attached to the display panel DP through an adhesive layer.

The anti-reflection layer RPL may be disposed on the input sensing part ISP. The anti-reflection layer RPL may be provided on (e.g., directly on) the input sensing part ISP, or be coupled to the input sensing part ISP through an adhesive layer. The anti-reflection layer RPL may be defined as a film that prevents the reflection of external light. The anti-reflection layer RPL may reduce the reflectance of external light incident from above the display device DD toward the display panel DP.

In case that external light traveling toward the display panel DP is reflected by the display panel DP and provided for an external user again, the external light may be visible to the user like a mirror. To prevent this phenomenon, the anti-reflection layer RPL may include, for example, multiple color filters that emit the same colors as pixels of the display panel DP.

The color filters may filter the external light to have the same colors as those of the pixels, respectively. The external light may be invisible to the user. However, an embodiment of the disclosure is not limited thereto, and the anti-reflective layer RPL may include a polarizing film for reducing the reflectance of the external light. The polarizing film may include a retarder and/or a polarizer.

The window WIN may be disposed on the anti-reflective layer RPL. The window WIN may be provided on (e.g., directly on) the anti-reflective layer RPL, or be coupled to the anti-reflective layer RPL through an adhesive layer. The window WIN may protect the display panel DP, the input sensing part ISP, and the anti-reflection layer RPL against external scratches and impact.

The panel protective film PF may be disposed below the display panel DP. The panel protective film PF may be provided below (e.g., directly below) the display panel DP, or be coupled to the display panel DP through an adhesive layer. The panel protective layer PF may protect a lower portion of the display panel DP. The panel protective layer PF may include a flexible plastic material such as polyethylene terephthalate (PET).

FIG. 13 is a view illustrating an example of a schematic cross-section of the display panel illustrated in FIG. 12.

As an example, FIG. 13 illustrates a schematic cross-section of the display panel DP viewed in the second direction DR2.

Referring to FIG. 13, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display area DA and a non-display area NDA around the display area DA. The substrate SUB may include a flexible plastic material such as polyimide (P1). The display element layer DP-OLED may be disposed on the display area DA.

Multiple pixels may be disposed in the display area DA. Each of the pixels may include a light emitting element electrically connected to a transistor, which may be disposed on the circuit element layer DP-CL, and disposed in the display element layer DP-OLED.

The thin-film encapsulation layer TFE may be disposed on the circuit element layer DP-CL so as to cover the display element layer DP-OLED. The thin-film encapsulation layer TFE may include inorganic layers, and an organic layer between the inorganic layers. The inorganic layers may protect the pixels against moisture/oxygen. The organic layer may protect the pixels PX against foreign material such as dust particles.

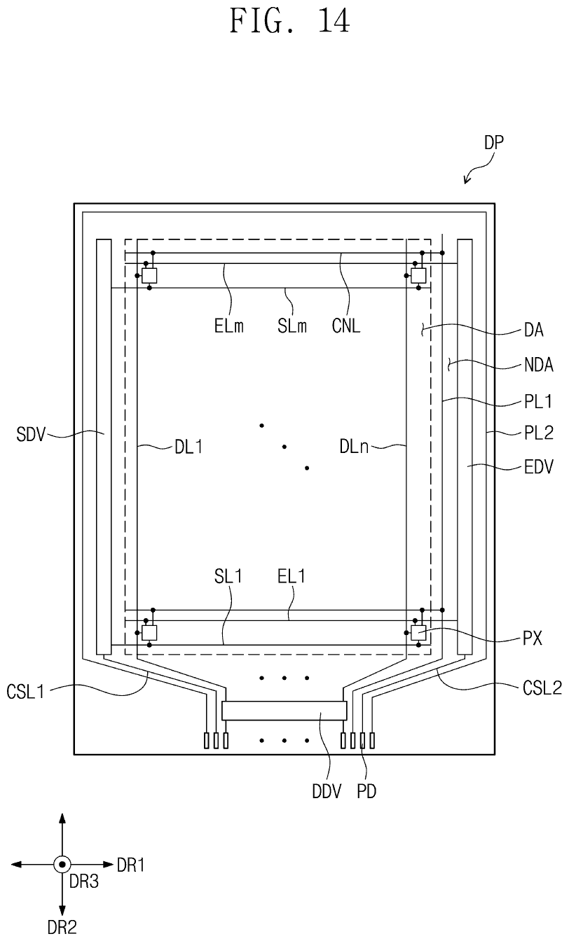

FIG. 14 is a plan view of the display panel illustrated in FIG. 13.

Referring to FIG. 14, the display device DD may include a display panel DP, a scan driver SDV, a data driver DDV, an emission driver EDV, and multiple pads PD. The display panel DP may include a display area DA and a non-display area NDA surrounding the display area DA.

The display panel DP may include multiple pixels PX, multiple scan lines SL1 to SLm, multiple data lines DLI to DLn, multiple emission lines EL1 to ELm, first and second control lines CSL1 and CSL2, first and second power lines PL1 and PL2, and connection lines CNL. Here, m and n may be each a natural number.

The pixels PX may be disposed on the display area DA. The scan driver SDV and the emission driver EDV may be disposed in the non-display area NDA adjacent to long sides of the display panel DP, respectively. The data driver DDV may be disposed in the non-display area NDA adjacent to any one of short sides of the display panel DP. The data driver DDV may be adjacent to a lower end of the display panel DP in a plan view.

The scan lines SL1 to SLm may extend in the first direction DR1 to be electrically connected to the pixels PX and the scan driver SDV. The data lines DLI to DLn may extend in the second direction DR2 to be electrically connected to the pixels PX and the data driver DDV. The emission lines EL1 to ELm may extend in the first direction DR1 to be electrically connected to the pixels PX and the emission driver EDV.

The first power line PL1 may extend in the second direction DR2 to be disposed in the non-display area NDA. The first power line PL1 may be disposed between the display area DA and the emission driver EDV. However, an embodiment of the disclosure is not limited thereto, and the first power line PL1 may be disposed between the display area DA and the scan driver SDV.

The connection lines CNL may extend in the first direction DR1, and be arranged in the second direction DR2. The connection lines CNL may be electrically connected to the first power line PL1 and the pixels PX. A first voltage may be applied to the pixels PX through the first power line PL1 and the connection lines CNL, which may be electrically connected to each other.

The second power line PL2 may be disposed in the non-display area NDA. The second power line PL2 may extend along the long sides of the display panel DP and another short side of the display panel DP, on which the data driver DDV may not be disposed. The second power line PL2 may be disposed at an outer position of each of the scan driver SDV and the emission driver EDV.

Although not illustrated, the second power line PL2 may extend toward the display area DA to be electrically connected to the pixels PX. A second voltage having a lower level than the first voltage may be applied to the pixels PX through the second power line PL2.

A first control line CSL1 may be electrically connected to the scan driver SDV, and extend toward the lower end of the display panel DP in a plan view. A second control line CSL2 may be electrically connected to the emission driver EDV, and extend toward the lower end of the display panel DP in a plan view. The data driver DDV may be disposed between the first control line CSL1 and the second control line CSL2.

The pads PD1 may be disposed on the display panel DP. The pads PD1 may be more adjacent to the lower end of the display panel DP than the data driver DDV is. The data driver DDV, the first power line PL1, the second power line PL2, the first control line CSL1, and the second control line CSL2 may be electrically connected to the pads PD. The data lines DLI to DLn may be electrically connected to the data driver DDV, and the data driver DDV may be electrically connected to the pads PD corresponding to the data lines DLI to DLn.

Although not illustrated, the display device DD may further include a timing controller for controlling an operation of each of the scan driver SDV, the data driver DDV, and the emission driver EDV, and a voltage generator for generating the first and second voltages. The timing controller and the voltage generator may be electrically connected to the pads PD corresponding thereto through a printed circuit board.

The scan driver SDV may generate multiple scan signals, and the scan signals may be applied to the pixels PX through the scan lines SL1 to SLm. The data driver DDV may generate multiple data voltages, and the data voltages may be applied to the pixels PX through the data lines DLI to DLn. The emission driver EDV may generate multiple emission signals, and the emission signals may be applied to the pixels PX through the emission lines EL1 to ELm.

The pixels PX may be provided with the data voltages in response to the scan signals. The pixels PX may display an image by emitting light with brightness corresponding to the data voltages in response to the emission signals. An emission time of the pixels PX may be controlled by the emission signals.

The display panel DP may be rolled in the second direction DR2. The display panel DP may be rolled starting from a side of the display panel DP, which may be adjacent to the data driver DDV. However, an embodiment of the disclosure is not limited thereto, and the display panel DP may be rolled starting from another side of the display panel DP, which may be opposite to the side of the display panel DP.

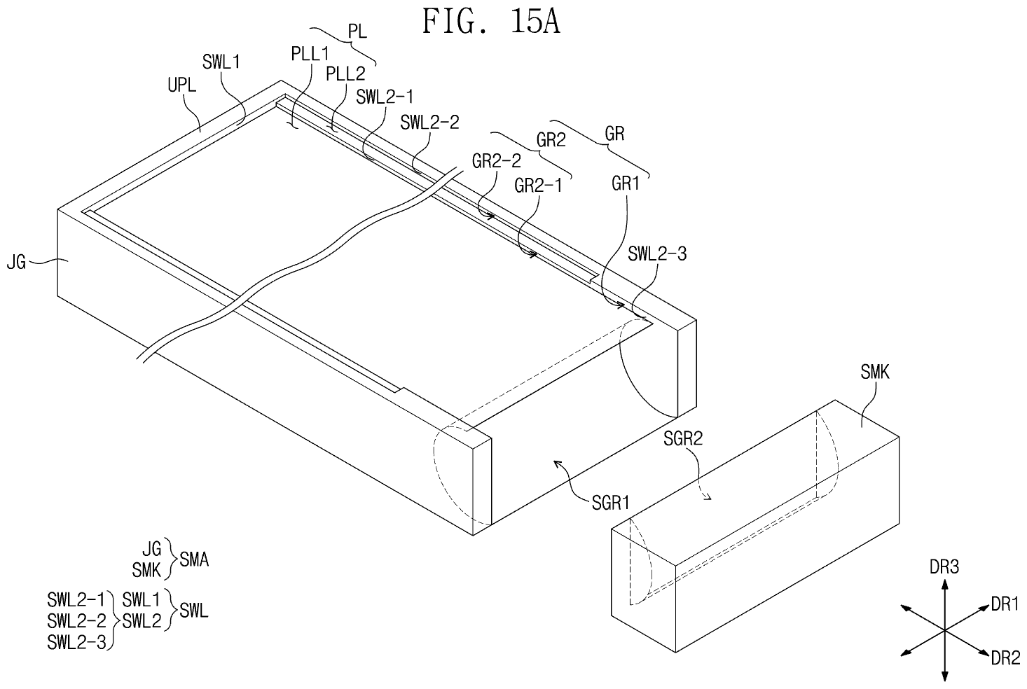

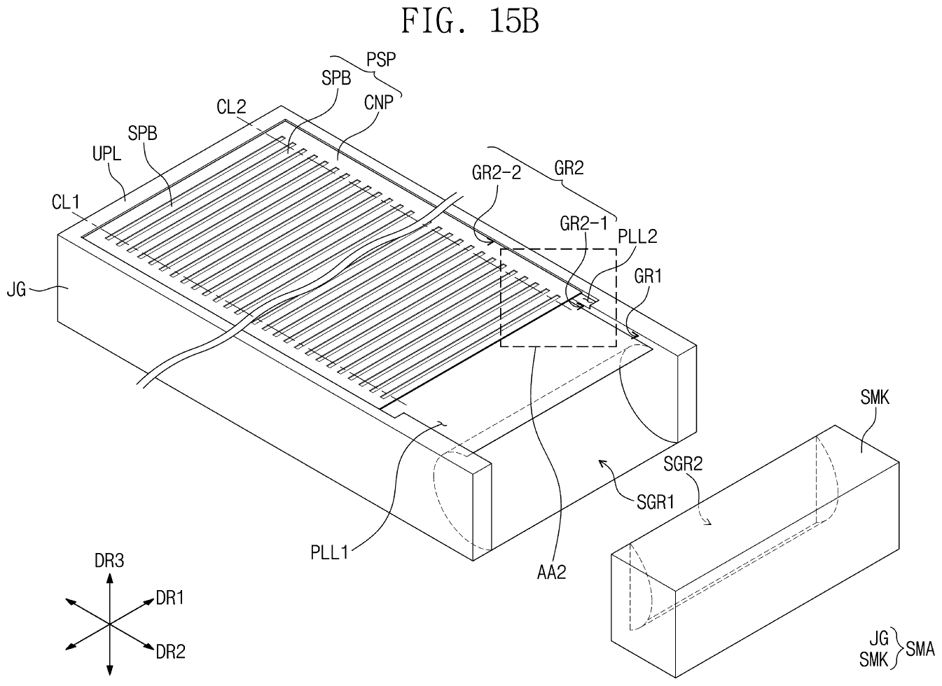

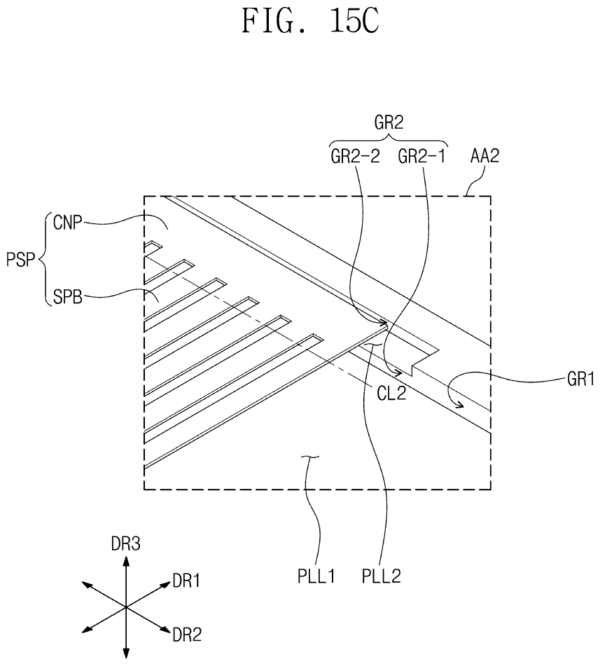

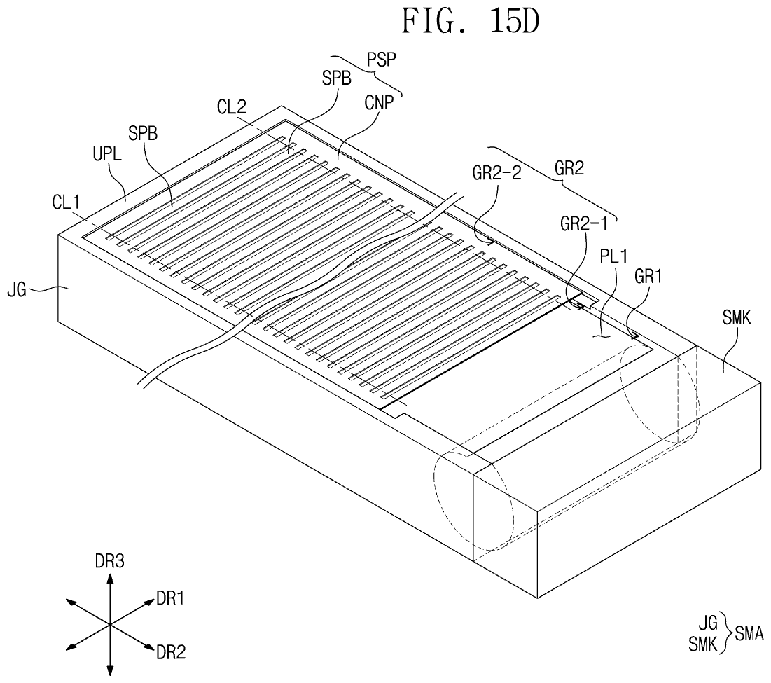

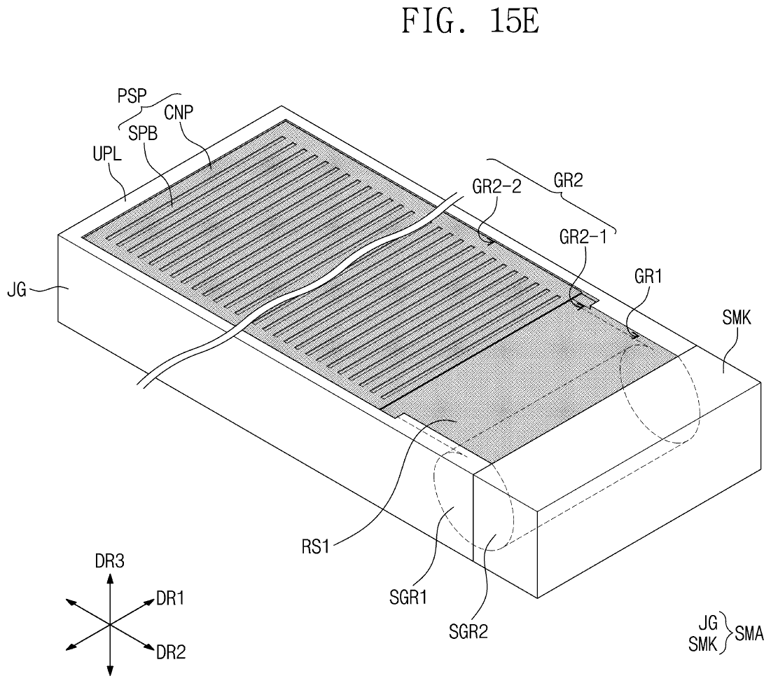

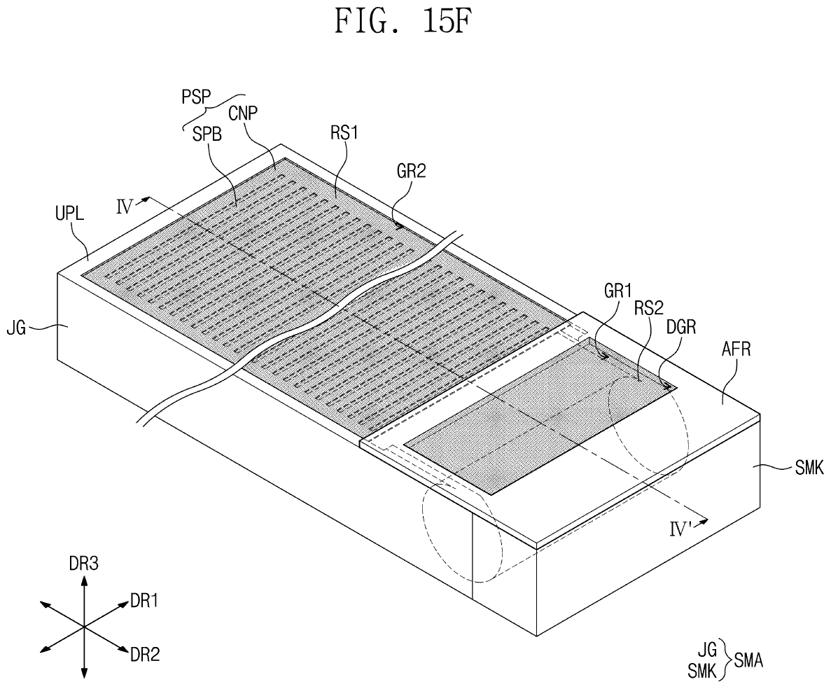

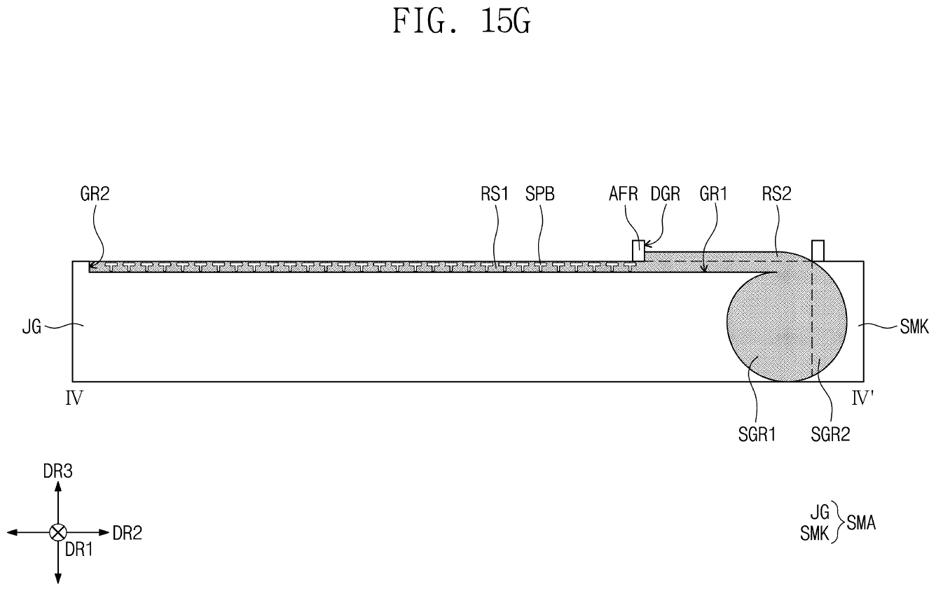

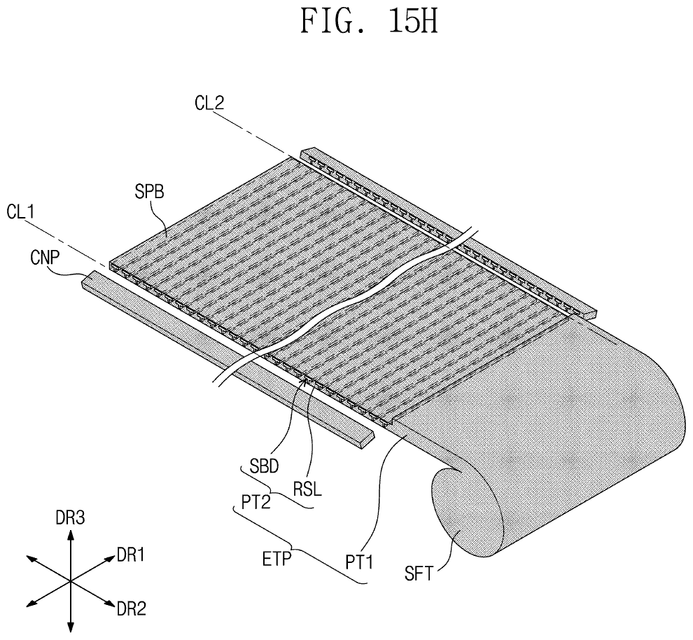

FIGS. 15A to 15H are views for explaining a method for manufacturing the support part illustrated in FIG. 5.

As an example, FIGS. 15A to 15F and 15H are perspective views, and FIG. 15G is a schematic cross-sectional view taken along line IV-IV′ illustrated in FIG. 15F.

As an example, FIG. 15C is an enlarged perspective view of a second area AA2 illustrated in FIG. 15B.

An extension part ETP and a shaft SFT in FIG. 15H are the same as the extension part ETP and the shaft SFT in FIG. 3, respectively, and thus description thereof will be omitted or provided shortly.

Referring to FIGS. 5 and 15A, a method for manufacturing the extension part ETP and the shaft SFT may include a step of preparing a jig JG. An apparatus SMA for manufacturing the extension part ETP and the shaft SFT (hereinafter referred to as the “apparatus”) may include the jig JG and a shaft forming part SMK. The jig JG and the shaft forming part SMK may be arranged in the second direction DR2. An anti-fingerprint coating (AF coating) may be applied onto a surface of each of the jig JG and the shaft forming part SMK.

As an example, the jig JG may have a rectangular parallelepiped shape. However, the shape of the jig JG is not limited thereto. The jig JG may include a top surface UPL defined by the first direction DR1 and the second direction DR2. As an example, the top surface UPL of the jig JG may have a rectangular shape in a plan view.

A groove GR may be defined in the top surface UPL of the jig JG. The groove GR may extend from the top surface UPL of the jig JG toward a bottom surface of the jig JG in a direction opposite to the third direction DR3. The groove GR may be defined by side surfaces SWL and a floor surface PL of the jig JG.

The floor surface PL may include a first floor surface PLL1 and multiple second floor surfaces PLL2. The second floor surfaces PLL2 may be disposed, respectively, at both sides of the first floor surface PLL1 that may be opposite to each other in the first direction DR1, in a plan view.

The first floor surface PLL1 may have a rectangular shape having short sides extending in the first direction DR1 and having long sides extending in the second direction DR2 in a plan view. Each of the second floor surfaces PLL2 may have a rectangular shape having short sides extending in the first direction DR1 and having long sides extending in the second direction DR2 in a plan view.

A length of the first floor surface PLL1 in the first direction DR1 may be greater than a length of each of the second floor surfaces PLL2 in the first direction DR1. A length of the first floor surface PLL1 in the second direction DR2 may be greater than a length of the second floor surface PLL2 in the second direction DR2. For example, a surface area of the first floor surface PLL1 may be greater than a surface area of the second floor surfaces PLL2.

A height of the first floor surface PLL1 may be less than a height of each of the second floor surfaces PLL2. The first floor surface PLL1 and each of the second floor surfaces PLL2 may be disposed to have a stepped portion therebetween. A height of each of the second floor surfaces PLL2 may be less than a height of the top surface UPL of the jig JG. The top surface UPL of the jig JG and each of the second floor surfaces PLL2 may be disposed to have a stepped portion therebetween.

The side surfaces SWL may include a first side surface SWL1 and multiple second side surfaces SWL2. The first side surface SWL1 may be disposed at one of both sides of the first floor surface PLL1 that may be opposite to each other in the second direction DR2. The one of both the sides of the first floor surface PLL1 that may be opposite to each other in the second direction DR2 may be defined as a side opposite to another side adjacent to the shaft forming part SMK. The first side surface SWL1 may be disposed between (2-2)-th side surfaces SWL2-2 to be described later, which face each other in the first direction DR1.

The second side surfaces SWL2 may be defined as inner side surfaces of the groove GR, which face each other in the first direction DR1. The second side surfaces SWL2 may include (2-1)-th side surfaces SWL2-1, the (2-2)-th side surfaces SWL2-2, and (2-3)-th side surfaces SWL2-3.

The (2-2)-th side surfaces SWL2-2 may be disposed on the (2-1)-th side surfaces SWL2-1, respectively. The (2-2)-th side surfaces SWL2-2 may be more adjacent to the top surface UPL of the jig JG than the (2-1)-th side surfaces SWL2-1 are. A distance between the (2-1)-th side surfaces SWL2-1 facing each other in the first direction DR1 may be less than a distance between the (2-2)-th side surfaces SWL2-2 facing each other in the first direction DR1.

The (2-3)-th side surfaces SWL2-3 may be arranged with the (2-1)-th side surfaces SWL2-1, respectively, in the second direction DR2. The (2-1)-th side surfaces SWL2-1 and the (2-3)-th side surfaces SWL2-3 may be disposed on substantially the same plane. The (2-3)-th side surfaces SWL2-3 may protrude from the (2-2)-th side surfaces SWL2-2 toward the first floor surface PLL1. The (2-3)-th side surfaces SWL2-3 may be more adjacent to the first floor surface PLL1 than the (2-2)-th side surfaces SWL2-2 are. For example, a distance between the (2-3)-th side surfaces SWL2-3 facing each other in the first direction DR1 may be less than the distance between the (2-2)-th side surfaces SLW2-2 facing each other in the first direction DR1.

A length of each of the (2-3)-th side surfaces SWL2-3 in the third direction DR3 may be equal to the sum of a length of each of the (2-1)-th side surfaces SWL2-1 in the third direction DR3 and a length of each of the (2-2)-th side surfaces SLW2-2 in the third direction DR3.

The groove GR may include a first groove GR1 and a second groove GR2. The first groove GR1 and the second groove GR2 may be defined to continue in the second direction DR2. The second groove GR2 may extend from the first groove GR1 in the second direction DR2.

The first groove GR1 may be defined by the first floor surface PLL1 and the (2-3)-th side surfaces SWL2-3. The second groove GR2 may be defined by the first and second floor surfaces PLL1 and PLL2 and the (2-1)-th and (2-2)-th side surfaces SWL2-1 and SWL2-2.

The second groove GR2 may include a (2-1)-th groove GR2-1 and a (2-2)-th groove GR2-2. The (2-1)-th groove GR2-1 may be defined by the first floor surface PLL1 and the (2-1)-th side surfaces SWL2-1. The (2-2)-th groove GR2-2 may be defined by the second floor surface PLL2 and the (2-2)-th side surfaces SLW2-2. The (2-1)-th groove GR2-1 and the (2-2)-th groove GR2-2 may be defined to continue in the third direction DR3. The (2-2)-th groove GR2-2 may be more adjacent to the top surface UPL of the jig JG than the (2-1)-th groove GR2-1 is.

A first shaft groove SGR1 may be defined in one of two opposing side surfaces of the jig JG which may be opposite to each other in the second direction DR2. The side surface of the jig JG that includes the first shaft groove SGR1 may have a surface concave in the second direction DR2. The side surface of the jig JG that includes the first shaft groove SGR1 may connect the top surface and the bottom surface of the jig JG to each other. As an example, the first shaft groove SGR1 may have a shape corresponding to a portion of a circle. The side surface of the jig JG that includes the first shaft groove SGR1 may be defined as a side surface adjacent to the first groove GR1.

As an example, the shaft forming part SMK may have a rectangular parallelepiped shape. However, the shape of the shaft forming part SMK is not limited thereto.

A second shaft groove SGR2 may be defined in one side surface of two opposing side surfaces of the shaft forming part SMK which may be opposite to each other in the second direction DR2. The side surface of the shaft forming part SMK that includes the second shaft groove SGR2 may have a surface concave in the second direction DR2. The side surface of the shaft forming part SMK that includes the second shaft groove SGR2 may connect a top surface and a bottom surface of the shaft forming part SMK to each other. As an example, the second shaft groove SGR2 may have a shape corresponding to a portion of a circle. Substantially, the first shaft groove SGR1 and the second shaft groove SGR2 may be symmetrical in the second direction DR2. The side surface of the shaft forming part SMK that includes the second shaft groove SGR2 may be defined as a side surface facing the side surface of the jig JG that includes the first shaft groove SGR1.

Referring to FIGS. 15B and 15C, a step of disposing a preliminary support body PSP in the second groove GR2 may be performed after the jig JG may be prepared. The preliminary support body PSP may include support bars SPB and connecting parts CNP. The support bars SPB may extend in the first direction DR1, and be arranged in the second direction DR2. The connecting parts CNP may extend, respectively from both ends, which may be opposite to each other in the first direction DR1 of each of the support bars SPB in the second direction DR2. As an example, the support bars SPB and the connecting parts CNP may be integral with each other.

Cutting lines CL1 and CL2 may be disposed between the connecting parts CNP. The cutting lines CL1 and CL2 may be arranged in the first direction DR1, and extend in the second direction DR2.

The preliminary support body PSP may be disposed in the (2-2)-th groove GR2-2. Both sides, which may be opposite to each other in the first direction DR1, of the preliminary support body PSP may be disposed on top surfaces of the second floor surfaces PLL2. The connecting parts CNP may be disposed on the top surfaces of the second floor surfaces PLL2.

A height of a bottom surface of the preliminary support body PSP may be greater than the height of the first floor surface PLL1. The bottom surface of the preliminary support body PSP may be spaced apart from the first floor surface PLL1 in the third direction DR3. A space between the bottom surface of the preliminary support body PSP and the first floor surface PLL1 may be the (2-1)-th groove GR2-1. A height of a top surface of the preliminary support body PSP may be less than the height of the top surface UPL of the jig JG. The top surface UPL of the jig JG and the top surface of the preliminary support body PSP may be disposed to have a stepped portion therebetween.

Referring to FIG. 15D, a step of providing the shaft forming part SMK on the side surface of the jig JG may be performed after the preliminary support body PSP may be disposed in the second groove GR2.

The shaft forming part SMK may move toward the side surface of the jig JG in the second direction DR2 so that the side surface of the shaft forming part SMK and the side surface of the jig JG may be in contact with each other. In case that the shaft forming part SMK and the jig JG are in contact with each other, the first shaft groove SGR1 and the second shaft groove SGR2 may be defined to continue in the second direction DR2.

The first shaft groove SGR1 may have an inner surface that may be a concave surface. A surface that connects the bottom surface of the jig JG and the first floor surface PLL1 to each other may be concave. The second shaft groove SGR2 may have an inner surface that may be a concave surface. The inner surface of the shaft forming part SMK may be a surface, which connects the bottom surface of the shaft forming part SMK and the top surface of the shaft forming part SMK to each other, and may be concave.

The bottom surface of the jig JG and the bottom surface of the shaft forming part SMK may be disposed on the same plane. The height of the first floor surface PLL1 of the jig JG may be less than a height of the top surface of the shaft forming part SMK. Accordingly, curvature of the inner surface of the first shaft groove SGR1 and curvature of the inner surface of the second shaft groove SGR2 may be different from each other.

Referring to FIG. 15E, a step of providing a resin may be performed after the shaft forming part SMK and the jig JG are connected (or attached) to each other. A first resin RS1 may be provided on the top surface of the jig JG. The first resin RS1 may be in a fluid state. The first resin RS1 in a fluid state may have a viscosity in a range of about 1 Cp to about 1000 Cp (centipoise).

The first resin RS1 may be filled in the first groove GR1, the second groove GR2, and the first and second shaft grooves SGR1 and SGR2. The first resin RS1 may be filled to be higher than the preliminary support body PSP disposed in the second groove GR2. The support bars SBP and the connecting parts CNP may be soaked (or immersed) in the first resin RS1. A height of a top surface of the first resin RS1 filled in the first groove GR1 may be the same as a height of a top surface of the first resin RS1 filled in the second groove GR2.

The first resin RS1 may be cured after the first resin RS1 is filled in the first groove GR1, the second groove GR2, and the first and second shaft grooves SGR1 and SGR2. As an example, the first resin RS1 may be cured by heat or ultraviolet rays.

A variation in volume of the first resin RS1 before and after the curing with respect to a volume of the first resin RS1 before the curing may be in a range of about 0% to about 0.1%. The cured resin may have an elastic modulus in a range of about 0.2 MPa to about 1 MPa.

Referring to FIGS. 15F and 15G, a step of disposing an additional frame AFR on the top surface of each of the jig JG and the shaft forming part SMK may be performed after the first resin RS1 is cured. The additional frame AFR may have a frame shape. The additional frame AFR may include long sides extending in the first direction DR1, and short sides extending in the second direction DR2. A dummy opening portion DGR may be defined by the additional frame AFR. The dummy opening portion DGR may have a rectangle shape in a plan view. The dummy opening portion DGR may be disposed above the first groove GR1. The dummy opening portion DGR may overlap the first groove GR1.

A step of providing a second resin RS2 in the dummy opening portion DGR may be performed after the additional frame AFR is disposed on the jig JG and the shaft forming part SMK. As illustrated in FIG. 15G, the second resin RS2 may be provided on the top surface of the first resin RS1 disposed in the first groove GR1. The second resin RS2 may not be provided on the top surface of the first resin RS1 disposed in the second groove GR2. Accordingly, a height of a top surface of the second resin RS2 overlapping the first groove GR1 may be greater than the height of the top surface of the first resin RS1 overlapping the second groove GR2. The second resin RS2 may be substantially the same as the first resin RS1.

Referring to FIGS. 15G and 15H, the second resin RS2 may be cured after the second resin RS2 is provided in the dummy opening portion DGR. As an example, the second resin RS2 may be cured by heat or ultraviolet rays. Hereinafter, a portion of the first resin RS1 and the second resin RS2, each of which overlaps the first groove GR1, may be defined as a dummy part PT1. Another portion which overlaps the second groove GR2 of the first resin RS1 may be defined as a support part PT2. The first resin RS1 disposed in the first shaft groove SGR1 and the second shaft groove SGR2 may be defined as a shaft SFT.

The preliminary support body PSP, the dummy part PT1, the support part PT2, and the shaft SFT may be separated from the jig JG and the shaft forming part SMK after the second resin RS2 is cured. The shaft SFT and the dummy part PT1 may be integral with each other. An outer circumference of the dummy part PT1 and an outer circumference of the shaft SFT may have the same curvature at a boundary between the dummy part PT1 and the shaft SFT. A top surface of the dummy part PT1 and the outer circumference of the shaft SFT may not have a stepped portion therebetween.

The support part PT2 may extend from the dummy part PT1 in the second direction DR2. A height of the top surface of the dummy part PT1 may be greater than a height of the top surface of the support part PT2. The top surface of the dummy part PT1 and the top surface of the support part PT2 may have a stepped portion therebetween.

Thereafter, a step of cutting the connecting parts CNP of the preliminary support body PSP from the support bars SPB may be performed. The connecting parts CNP and the support bars SPB may be cut along the cutting lines CL1 and CL2. In case that the connecting parts CNP are cut from the support bars SPB, both sides which may be opposite to each other in the first direction DR1 of each of the support bars SPB may be exposed from the support bars SPB to the outside.

Referring to FIGS. 3 and 15H, although not illustrated, the display module DM may be disposed on the top surface of the support part PT2. A thickness of the dummy part PT1 may be substantially equal to the sum of a thickness of the support part PT2 and a thickness of the display module DM. As an example, a difference between the height of the front surface of the dummy part PT1 and a height of a top surface of the display module DM may be in a range of about 0 micrometer to about 50 micrometers. Accordingly, a stepped portion may not be generated between the dummy part PT1 and the top surface of the display module DM. Thus, surface quality of the display panel DP may be improved.

According to the embodiment of the disclosure, the support part disposed below the display panel may include the shaft and the extension part. The extension part may be and the shaft may be integral with each other so that the stepped portion may not be generated at the boundary between the extension part and the shaft. Accordingly, in case that the display panel is rolled on the shaft, the crease may not be generated on the portion of the display panel overlapping the boundary between the extension part and the shaft. Therefore, the surface quality of the display panel may be improved.

Although the embodiments of the disclosure have been described, it is understood that the disclosure should not be limited to these embodiments but various changes and modifications can be made by one ordinary skilled in the art within the spirit and scope of the disclosure as hereinafter claimed. Therefore, the technical scope of the disclosure is not limited to the contents described in the detailed description of the specification, but should be determined by the claims.

What is claimed is:

1. A display device comprising:
a display module;
a support part disposed below the display module;
a dummy part extending to an end of the support part; and
a shaft extending to an end of the dummy part, the shaft having a rotary axis extending in a first direction the display module being wound on or unwound from the shaft,
wherein the support part, the dummy part, and the shaft comprise a same resin.

2. The display device of claim 1, wherein a thickness of the dummy part is greater than a thickness of the support part.

3. The display device of claim 2, wherein a difference between a height of a top surface of the display module disposed on the support part and a height of a top surface of the dummy part is in a range of about 0 micrometer to about 50 micrometers.

4. The display device of claim 1, wherein in case that the display module is wound on the shaft, a difference between a distance from the rotary axis to an outer circumference of the shaft and a distance from the rotary axis to an outer circumference of the dummy part is in a range of about 0 micrometer to about 50 micrometers at a boundary between the shaft and the dummy part.

5. The display device of claim 1, wherein a radius of the shaft, which is defined as a distance from the rotary axis to an outer circumference of the shaft, is variable.

6. The display device of claim 1, wherein the support part comprises:
a resin layer comprising the resin; and
a support body disposed in the resin layer.

7. The display device of claim 6, wherein the support body comprises a plurality of support bars extending in the first direction and arranged in a second direction intersecting the first direction.

8. The display device of claim 6, wherein the support body comprises a support plate in which a plurality of opening portions are defined.

9. The display device of claim 1, wherein the support part, the dummy part, and the shaft are integral with each other.

10. The display device of claim 1, wherein the shaft comprises:
a sub-shaft extending in the first direction; and
a coating part configured to surround the sub-shaft, the coating part containing the resin.

11. The display device of claim 1, wherein the resin has an elastic modulus in a range of about 0.2 MPa to about 1 MPa.

12. The display device of claim 1, wherein in case that the display module is wound on the shaft, a bottom surface of the dummy part is in contact with an outer circumference of the shaft.

13. The display device of claim 12, wherein a bottom surface of the support part is in contact with a portion of the dummy part and a portion of the shaft, each of which is adjacent to a boundary between the dummy part and the shaft.

14. A display device comprising:
a display module;
a shaft which comprises a first stepped portion provided at an outer circumference of the shaft; and
an extension part extending from the first stepped portion, the extension part being wound on or unwound from the shaft together with the display module, wherein
the extension part comprises:
a dummy part extending from the first stepped portion; and
a support part extending from the dummy part in a first direction, the support part being disposed below the display module, and
a second stepped portion is provided at a boundary between the dummy part and the support part.

15. The display device of claim 14, wherein a curvature of the shaft adjacent to the first stepped portion is equal to a curvature of the dummy part adjacent to the first stepped portion.

16. The display device of claim 15, wherein in case that the display module is wound, the support part is wound along at least one of an outer circumference of the dummy part or an outer circumference of the shaft.

17. The display device of claim 14, wherein in case that the display module is wound, a curvature of the dummy part adjacent to the second stepped portion is equal to a curvature of the support part adjacent to the second stepped portion.

18. The display device of claim 14, wherein a difference between a thickness of the dummy part and a sum of a thickness of the support part and a thickness of the display module is in a range of about 0 micrometer to about 50 micrometers.

19. The display device of claim 14, wherein the shaft has at least two different curvatures.

20. The display device of claim 14, wherein the support part, the dummy part, and the shaft are integral with each other.

21. The display device of claim 14, wherein the support part comprises:
a resin layer comprising a resin; and
a support layer disposed in the resin layer.

22. The display device of claim 14, wherein the shaft comprises:
a coating part comprising a resin; and
a sub-shaft surrounded by the coating part.
